(19) United States
(12) Patent Application Publication
(10) Pub. No.: US 2004/0177876 A1
(43) Pub. Date: Sep. 16, 2004

(54) Spatially optimized thermoelectric module

(75) Inventor: Adrian Hightower, Pasadena (CA)

Correspondence Address: ADRIAN HIGHTOWER, 120 S. SIERRA MADRE BOULEVARD #304, PASADENA, CA, 91107, US

(73) Assignee: ENHANCED ENERGY SYSTEMS, INC.

(21) Appl. No.: 10/385,940

(22) Filed: Mar. 10, 2003

(51) Int. Cl. H01L 35/00; H01L 37/00; H01L 35/28

(52) U.S. Cl. 136/211; 136/212

(57) ABSTRACT

A semiconductor thermoelectric module includes a first semiconductor element formed from a first composition. A second semiconductor element is formed from a second composition. The second semiconductor element is connected electrically in series with the first semiconductor element via an electrical conductor, and the second composition differs from the first composition.

### BACKGROUND OF THE INVENTION

1. Technical Field

Embodiments of the present invention are directed to thermoelectric modules/generators. More specifically, embodiments of the present invention are directed to optimizing the design of thermoelectric modules relative to a temperature gradient across one of its faces.

2. Discussion of the Related Art

A thermoelectric (TE) module/generator (see FIG. 1) converts heat into electricity with no moving parts. As heat moves past the thermoelectric module, it causes an electrical current to flow. Thermoelectric modules utilize a physics principle known as the Seebeck effect, discovered in 1821. The Seebeck effect states that if two wires of different materials (such as copper and iron) are joined at their ends, forming two junctions, and one junction is held at a higher temperature than the other junction, a voltage difference will arise between the two junctions. Most thermoelectric modules currently in use today to generate electricity are formed of pylons of semiconductor materials, typically entirely of bismuth telluride (Bi₂Te₃), which are good conductors of electricity but poor conductors of heat. Each pylon generates a voltage difference dependent upon the temperature difference between its faces. These pylons are connected in series electrically and in parallel thermally in order to obtain a single module. These semiconductors are typically heavily doped to create an excess of electrons (n-type) or a deficiency of electrons (p-type). An n-type semiconductor develops a negative charge on the “cold” side, and a p-type semiconductor will develop a positive charge on the “cold” side.

When heat is focused onto a thermoelectric module through convective flow, there is a temperature distribution over the surface (or face) of the thermoelectric module. The region where the center of the exhaust flow contacts the surface of the thermoelectric module is the greatest focus of heat and thus has the highest temperature. The temperature on the surface of the thermoelectric module decreases further away from the exhaust center. Conventional thermoelectric modules and generators (formed from a plurality of thermoelectric module “chips”) are formed of pylons made entirely of a single composition, typically, bismuth telluride (Bi₂Te₃), and are not efficiently manufactured to take into account the distribution of temperatures across the various pylon faces within a thermoelectric module or generator. The state of the art thermoelectric modules include pylons formed of different material segments (segmented thermoelectric modules). For example, each pylon segment may be formed of different material compositions. The geometry and material composition of each segment may be chosen to match the temperature gradient along the pylon to maximize efficiency of thermoelectric conversion. However, manufacture of segmented pylons is expensive, difficult, and presents enormous technical challenges.

### BRIEF DESCRIPTION OF THE DRAWINGS

FIG. 1 illustrates a thermoelectric module according to the prior art;

FIG. 2 illustrates a thermoelectric module according to an embodiment of the present invention;

FIG. 3A illustrates a top view of a thermoelectric module according to an embodiment of the present invention;

FIG. 3B illustrates a side view of the thermoelectric module of FIG. 3A installed in a heat flow path according to an embodiment of the present invention;

FIG. 4 illustrates a graph of thermoelectric figures of merit (ZT) for a plurality of P-type semiconductor element composition materials as a function of temperature; and

FIG. 5 illustrates a geometric configuration of a thermoelectric module according to an embodiment of the present invention.

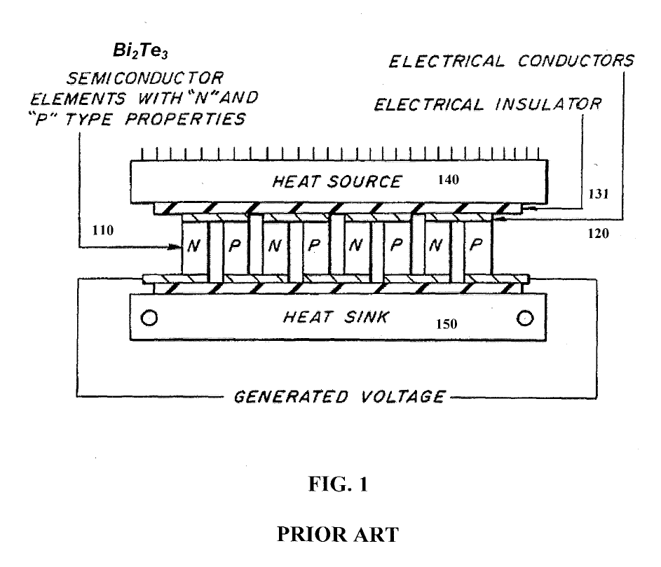

### DETAILED DESCRIPTION

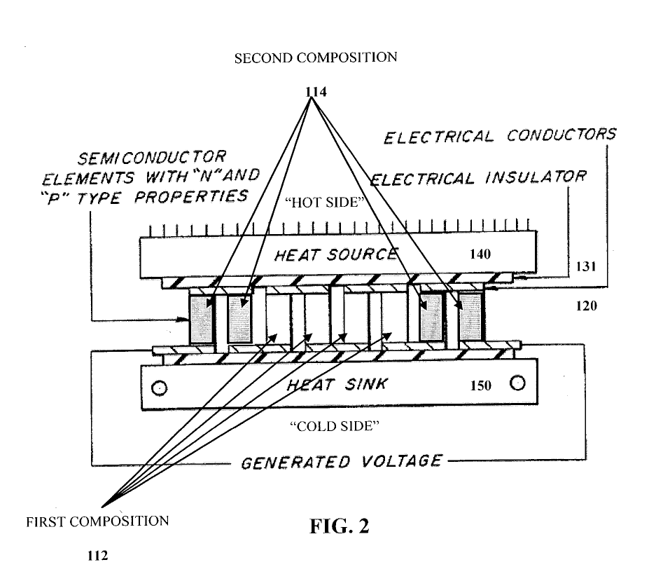

FIG. 2 illustrates a thermoelectric module according to an embodiment of the present invention. The thermoelectric module 200 includes a series of “N” and “P” doped semiconductor elements (or pylons) 112, 114 that are connected in series electrically via conductors 120 and in parallel thermally. Each of the semiconductor elements 112, 114 are thermally coupled on its opposite sides to a heat source 140 exchanger and a heat sink 150 exchanger, but are electrically insulated from these components by electrical insulation material 131 (e.g., PEEK™ polymer or Al₂O₃).

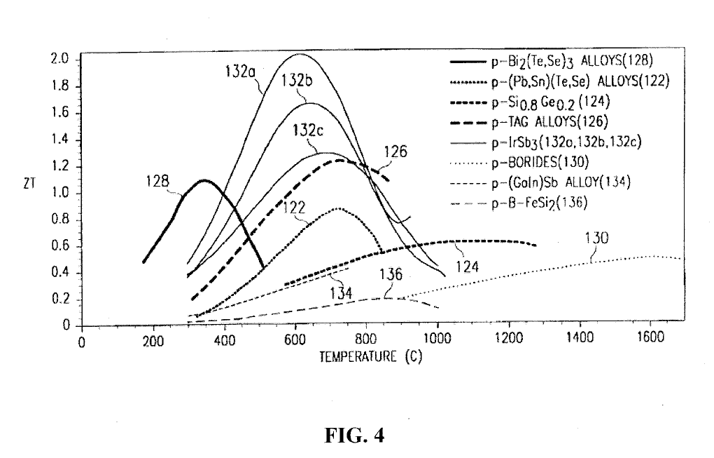

In order to optimize for the temperature gradient along the face of the thermoelectric module 200 due to the distribution of temperatures across the various pylon faces of the thermoelectric module 200 or generator, the semiconductor elements are formed of different material compositions. For example, more expensive, high-heat bearing material compositions may be utilized for those pylons near or at the focus of the heat flow at the face of the thermoelectric module 200, and less-heat bearing material compositions, and typically are less expensive, may be utilized for those pylons that are further away from the center of the thermoelectric module 200 and the focus of the heat flow. Referring to FIG. 2, for example, the semiconductor elements/pylons 112 near the center of the thermoelectric module 200, and in turn, are exposed to the highest heat flow, may be formed of a first composition that is optimized for high temperatures (e.g., Pb₂Te₃). The semiconductor elements/pylons 114 away from the center of the thermoelectric module 200 may be formed of a second composition that is optimized for a lesser temperature (e.g., Bi₂Te₃). A variety of different material compositions, including, but not limited to the following, may be utilized to form the semiconductor elements/pylons: FeSi₂, Zn₄Sb₃, CeFe₄Sb₁₂, SiGe, PbTe, and BiTe. Depending upon the price and performance goals of the thermoelectric module 200, various combination of different material compositions may be utilized in a thermoelectric module 200 (e.g., FeSi₂ are cheaper but have lower life expectancies and performance, while Pb₂Te₃ operate efficiently in high temperatures but are more expensive). Referring to FIG. 4, for example, the thermoelectric figures of merit (ZT), which are directly proportional to thermoelectric efficiency, are shown for a sample plurality of P-type semiconductor element composition materials as a function of temperature. ZT represents the coupling between electrical and thermal effects in a material, and is defined as: ZT=S²σT/κ, where S, σ, κ, and T are the Seebeck coefficient, electrical conductivity, thermal conductivity, and absolute temperature, respectively. The basic thermoelectric effects are the Seebeck and Peltier effects. As mentioned above, the Seebeck effect is the phenomenon underlying the conversion of heat energy into electrical power and is utilized in thermoelectric power generation. The complementary effect, the Peltier effect, is the phenomenon utilized in thermoelectric refrigeration and is related to heat absorption accompanying the passage of current through the junction of two dissimilar materials. Although the thermoelectric module 200 illustrated in FIG. 2 shows semiconductor elements 112, 114 each being formed of a different composition, respectively, more than two semiconductor element types, and thus, more than two compositions, may be implemented in a thermoelectric module 200 as well.

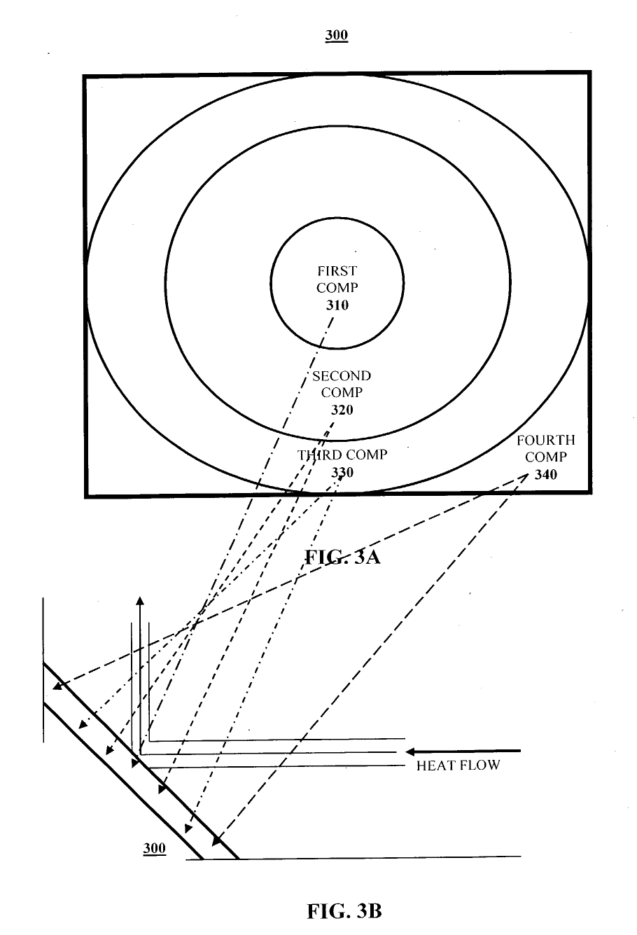

FIG. 3 A illustrates a top view of a thermoelectric module according to an embodiment of the present invention, and FIG. 3B illustrates a side view of the thermoelectric module of FIG. 3A installed in a heat flow path according to an embodiment of the present invention. The top view (FIG. 3A) illustrates a thermoelectric module 300 such that the semiconductor elements/pylons 310 at the center of the thermoelectric module 300 is formed of a first composition, while the semiconductor elements/pylons 320 that envelope/surround the first section 310 are formed of a second composition. A third section of semiconductor elements/pylons 330 that envelope/surround the second section 320 are formed of a third composition, and a fourth section of semiconductor elements/pylons 340 that envelope/surround the third section 330 are formed of a third composition. Although the thermoelectric module 300 illustrated in FIGS. 3A and 3B show four groups/sections of semiconductor elements/pylons 310, 320, 330, 340 each formed of a different composition, a configuration where two, three, and more than four compositions are utilized may also be implemented.

Referring to FIG. 3B and according to an embodiment of the present invention, the thermoelectric module 300 is arranged such that highest performing and most cost-effective material for the highest heat flow temperatures encountered by the thermoelectric module 300 is utilized for the semiconductor elements/pylons 310 at the center area of the thermoelectric module 300. A less high temperature bearing material may be utilized for the semiconductor elements/pylons 320 surrounding the first section 310. And progressively less high temperature bearing materials (and also lesser performing and less expensive materials) may be utilized for the semiconductor elements/pylons 330 in the third section and the semiconductor elements/pylons 340 in the fourth section, respectively. Accordingly, the temperatures across the face of the thermoelectric module 300 is highest at the center section 310, and progressively less towards the second section 320, the third section 330, and the fourth section 340.

A plurality of thermoelectric modules 200 may be arranged in a configuration as illustrated in FIGS. 3A and 3B such that each thermoelectric module 200 has semiconductor elements/pylons formed from a single material composition, and thermoelectric modules having semiconductor elements/pylons formed of a first composition 310 are placed at the center of the thermoelectric generator formed from a plurality of thermoelectric modules. Thermoelectric modules having semiconductor elements/pylons formed of a second composition 320 are placed surrounding the first section 310 of the thermoelectric generator. Thermoelectric modules having semiconductor elements/pylons formed of a third composition 330 are placed surrounding the second section 320 of the thermoelectric generator. And, thermoelectric modules having semiconductor elements/pylons formed of a fourth composition 340 are placed surrounding the third section 330 of the thermoelectric generator.

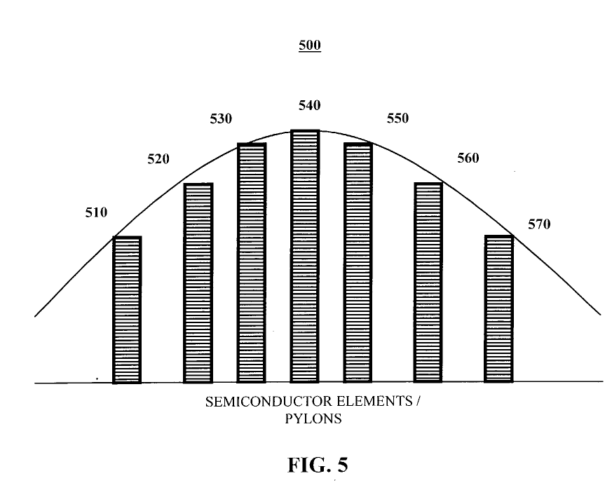

FIG. 5 illustrates a geometric configuration of a thermoelectric module according to an embodiment of the present invention. Each individual semiconductor element (pylon) 510, 520, 530, 540, 550, 560, 570 may be designed to optimize the temperature gradient along the face of a thermoelectric module 500. For example, the geometry (e.g., height, cross-section, girth, thickness, etc.) of each pylon within a thermoelectric module may be configured differently from each other. In the embodiment illustrated in FIG. 5, the semiconductor element 540 closest to the center of the thermoelectric module 500, and thus receiving the highest temperature, may be longer than the semiconductor elements 510, 570 that are further away from the center, thus receiving a lower temperature. By increasing the length of each pylon, for example, the path of heat conductance is increased, thus increasing the temperature differential between the “hot” side and the “cold” side of the thermoelectric module, and therefore improving its performance. Increasing or decreasing the other geometric aspects of a pylon, such as the cross-section, girth, thickness, etc., for example, also increases or shortens the heat path between the “hot” side and the “cold” side of the thermoelectric module as well. Accordingly, different geometric configurations of the pylons may be utilized depending on a particular application in order to optimize its performance, costs, etc.

The thermoelectric modules and generators according to embodiments of the present invention increases the overall efficiency of waste-heat generator systems by optimizing their design to the temperature gradients during standard operating conditions. Over the entire lifetime of the thermoelectric module and generator, the benefits are cumulative. Moreover, embodiments of the present invention permit thermoelectric modules and generators to be designed to optimize cost. By utilizing less-expensive materials in less critical regions (lower temperature, lower heat transfer regions), the overall cost of the system is reduced.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes that come within the meaning and range of equivalency of the claims are therefore intended to be embraced therein.

What is claimed is:

1. A semiconductor thermoelectric module, comprising:
a first semiconductor element formed from a first composition; and
a second semiconductor element formed from a second composition, wherein the second semiconductor element is connected electrically in series with the first semiconductor element via an electrical conductor, and the second composition differs from the first composition.

2. The semiconductor thermoelectric module according to claim 1, wherein the first semiconductor element is a P-type semiconductor material and the second semiconductor element is a N-type semiconductor material.

3. The semiconductor thermoelectric module according to claim 1, wherein the first semiconductor element is a N-type semiconductor material and the second semiconductor element is a P-type semiconductor material.

4. The semiconductor thermoelectric module according to claim 1, wherein the first semiconductor element and the second semiconductor element are connected thermally in parallel.

5. A semiconductor thermoelectric module, comprising:
a first section including a plurality of semiconductor elements formed from a first composition; and
a second section, adjacent to the first section, including a plurality of second semiconductor elements formed from a second composition, wherein the second composition differs from the first composition.

6. The semiconductor thermoelectric module according to claim 5, wherein the plurality of semiconductor elements are connected electrically in series alternating between a P-type semiconductor material and a N-type semiconductor material.

7. The semiconductor thermoelectric module according to claim 5, wherein the plurality of second semiconductor elements are connected electrically in series alternating between a P-type semiconductor material and a N-type semiconductor material.

8. The semiconductor thermoelectric module according to claim 5, wherein the second section envelopes the first section.

9. The semiconductor thermoelectric module according to claim 5, wherein the plurality of semiconductor elements are connected thermally in parallel.

10. The semiconductor thermoelectric module according to claim 5, wherein the plurality of second semiconductor elements are connected thermally in parallel.

11. The semiconductor thermoelectric module according to claim 5, wherein the first composition provides higher performance of thermoelectric generation than the second composition.

12. The semiconductor thermoelectric module according to claim 5, wherein the first composition is more expensive than the second composition.

13. A semiconductor thermoelectric generator, comprising:
a first thermoelectric module, including a plurality of semiconductor elements formed from a first composition connected electrically in series via electrical conductors to a first side of the first thermoelectric module and to a second side of the first thermoelectric module; and
a second thermoelectric module adjacent to the first thermoelectric module, including a plurality of second semiconductor elements formed from a second composition connected electrically in series via second electrical conductors to a first side of the second thermoelectric module and to a second side of the second thermoelectric module, wherein the second composition differs from the first composition.

14. The semiconductor thermoelectric generator according to claim 13, wherein the plurality of semiconductor elements are connected electrically in series alternating between a P-type semiconductor material and a N-type semiconductor material.

15. The semiconductor thermoelectric generator according to claim 13, wherein the plurality of second semiconductor elements are connected electrically in series alternating between a P-type semiconductor material and a N-type semiconductor material.

16. The semiconductor thermoelectric generator according to claim 13, wherein the plurality of semiconductor elements are connected thermally in parallel.

17. The semiconductor thermoelectric generator according to claim 13, wherein the plurality of second semiconductor elements are connected thermally in parallel.

18. The semiconductor thermoelectric generator according to claim 13, wherein the first side of the first thermoelectric module is a hot side and the second side of the first thermoelectric module is a cold side.

19. The semiconductor thermoelectric generator according to claim 13, wherein the first side of the second thermoelectric module is a hot side and the second side of the second thermoelectric module is a cold side.

20. The semiconductor thermoelectric generator according to claim 13, wherein the first composition provides higher performance of thermoelectric generation than the second composition.

21. The semiconductor thermoelectric generator according to claim 13, wherein the first composition is more expensive than the second composition.

22. A thermoelectric module, comprising:
first means for generating electricity from heat formed from a first composition;
second means for generating electricity from heat located adjacent to the first means formed from a second composition, wherein the second composition differs from the first composition.

23. The thermoelectric module according to claim 22, wherein the first means includes a plurality of semiconductor elements connected electrically in series alternating between a P-type semiconductor material and a N-type semiconductor material.

24. The thermoelectric module according to claim 22, wherein the second means includes a plurality of semiconductor elements connected electrically in series alternating between a P-type semiconductor material and a N-type semiconductor material.

25. The thermoelectric module according to claim 22, wherein the second means envelopes the first means.

26. The thermoelectric module according to claim 22, wherein the first means includes a plurality of semiconductor elements connected thermally in parallel.

27. The thermoelectric module according to claim 22, wherein the second means includes a plurality of semiconductor elements connected thermally in parallel.

28. The thermoelectric module according to claim 22, wherein the first composition provides higher performance of thermoelectric generation than the second composition.

29. The thermoelectric module according to claim 22, wherein the first composition is more expensive than the second composition.

30. The thermoelectric module according to claim 22, wherein the first means is a P-type semiconductor material and the second means is a N-type semiconductor material.

31. The thermoelectric module according to claim 22, wherein the first means is a N-type semiconductor material and the second means is a P-type semiconductor material.

32. The thermoelectric module according to claim 22, wherein the first means and the second means are connected thermally in parallel.

33. A semiconductor thermoelectric module, comprising:
a first section including a plurality of semiconductor elements formed from a first composition;
a second section, adjacent to the first section, including a plurality of second semiconductor elements formed from a second composition; and
a third section, adjacent to the second section, including a plurality of third semiconductor elements formed from a third composition, wherein the second composition differs from the first composition.

34. The semiconductor thermoelectric module according to claim 33, wherein the third composition differs from the second composition and the first composition.

35. The semiconductor thermoelectric module according to claim 33, wherein the plurality of semiconductor elements are connected electrically in series alternating between a P-type semiconductor material and a N-type semiconductor material.

36. The semiconductor thermoelectric module according to claim 33, wherein the plurality of second semiconductor elements are connected electrically in series alternating between a P-type semiconductor material and a N-type semiconductor material.

37. The semiconductor thermoelectric module according to claim 33, wherein the plurality of third semiconductor elements are connected electrically in series alternating between a P-type semiconductor material and a N-type semiconductor material.

38. The semiconductor thermoelectric module according to claim 33, wherein the second section envelopes the first section.

39. The semiconductor thermoelectric module according to claim 33, wherein the third section envelopes the second section.

40. The semiconductor thermoelectric module according to claim 33, wherein the plurality of semiconductor elements are connected thermally in parallel.

41. The semiconductor thermoelectric module according to claim 33, wherein the plurality of second semiconductor elements are connected thermally in parallel.

42. The semiconductor thermoelectric module according to claim 33, wherein the plurality of third semiconductor elements are connected thermally in parallel.

43. The semiconductor thermoelectric module according to claim 33, wherein the first composition provides higher performance of thermoelectric generation than the second composition.

44. The semiconductor thermoelectric module according to claim 33, wherein the first composition is more expensive than the second composition.

45. The semiconductor thermoelectric module according to claim 33, wherein the first composition provides higher performance of thermoelectric generation than the second composition, and the second composition provides higher performance of thermoelectric generation than the third composition.

46. The semiconductor thermoelectric module according to claim 33, wherein the first composition is more expensive than the second composition, and the second composition is more expensive than the third composition.
